(19) United States
(12) Patent Application Publication
(10) Pub. No.: US 2015/0168448 A1
(43) Pub. Date: Jun. 18, 2015

(54) TEST CARRIER

(71) Applicant: ADVANTEST CORPORATION, Tokyo (JP)

(72) Inventors: Kiyoto Nakamura, Miyagi (JP); Takashi Fujisaki, Gunma (JP); Hiroki Ichikawa, Gunma (JP)

(73) Assignee: ADVANTEST CORPORATION, Tokyo (JP)

(21) Appl. No.: 14/390,557

(22) PCT Filed: May 21, 2013
(86) PCT No.: PCT/JP2013/064076

§ 371 Date: Oct. 3, 2014

(30) Foreign Application Priority Data
May 23, 2012 (JP) 2012-117421

(51) Int. Cl. G01R 1/04; G01R 31/00

(52) U.S. Cl. CPC G01R 1/0408; G01R 31/003

(57) ABSTRACT

A test carrier includes a base film that holds a die and a cover film that overlaps the base film so as to cover the die. The cover film has a self-adhesive property and is more flexible than the base film. The base film has a through hole. The through hole is formed in the vicinity of a region of the base film which contacts the die.

### TECHNICAL FIELD

The present invention relates to a test carrier on which a die chip is temporarily mounted in order to test an electronic circuit, such as an integrated circuit, formed on a die.

For the designated countries which permit the incorporation by reference, the contents described and/or illustrated in Japanese Patent Application No. 2012-117421 filed on May 23, 2012 are incorporated by reference in the present application as a part of the description and/or drawings of the present application.

### BACKGROUND ART

As a test carrier on which a semiconductor chip in a bare chip state is temporarily mounted, a test carrier has been known in which a semiconductor chip is interposed between a contact sheet and a base film (for example, see Patent Document 1).

### CITATION LIST

### Patent Document

Patent Document 1: JP H07-263504 A

### DISCLOSURE OF THE INVENTION

### Problem to be Solved by the Invention

When air remains in a space of the test carrier, the air expands during a heating test, and the semiconductor chip deviates from the contact sheet. Therefore, there is a problem that it is impossible to perform the test in some cases.

An object of the invention is to provide a test carrier which enable a heating test to be stably performed.

### Means for Solving Problem

[1] According to the invention, there is provided a test carrier that accommodates an electronic device to be tested, the test carrier comprising: a connection means that connects an internal space to an outside, wherein the internal space accommodates the electronic device to be tested.

[2] In the above-mentioned invention, the test carrier may further comprise a prohibition means that allows a flow of gas from the internal space to the outside through the connection means and prohibits an object from entering the internal space from the outside through the connection means.

[3] According to the invention, there is provided a test carrier comprising a first member that holds an electronic device to be tested; and a second member that has a film shape and overlaps the first member so as to cover the electronic device to be tested, wherein at least one of the second member and the first member has a self-adhesive property, the second member is more flexible than the first member, at least one of the first member and the second member has a through hole, and the through hole is formed in the vicinity of a region of at least one of the first member and the second member which contacts the electronic device to be tested.

[4] In the above-mentioned invention, the test carrier may further comprise a filter that is stuck to at least one of the first member and the second member so as to cover an opening of the through hole.

[5] In the above-mentioned invention, the second member may be made of a material with the self-adhesive property.

[6] In the above-mentioned invention, the second member may be made of silicon rubber.

[7] In the above-mentioned invention, at least one of the second member and the first member may have a surface on which a layer with the self-adhesive property is formed.

### Effect of the Invention

According to the invention, air which remains in the internal space of the test carrier can be discharged to the outside by the connection means. Therefore, it is possible to stably perform a heating test.

In addition, according to the invention, air which remains around the electronic device to be tested can be discharged to the outside through the through hole that is formed in at least one of the first member and the second member. Therefore, it is possible to stably perform a heating test.

### BRIEF DESCRIPTION OF DRAWINGS

FIG. 1 is a flowchart illustrating a portion of a device manufacturing process in an embodiment of the invention;

FIG. 2 is an exploded perspective view illustrating a test carrier in the embodiment of the invention;

FIG. 3 is a cross-sectional view illustrating the test carrier in the embodiment of the invention;

FIG. 4 is an exploded cross-sectional view illustrating the test carrier in the embodiment of the invention;

FIG. 5 is an enlarged view illustrating a V portion illustrated in FIG. 4;

FIG. 6 is an exploded cross-sectional view illustrating a first modification of the test carrier in the embodiment of the invention;

FIG. 7 is an exploded cross-sectional view illustrating a second modification of the test carrier in the embodiment of the invention;

FIG. 8 is a cross-sectional view illustrating a modification of a cover member in the embodiment of the invention; and

FIG. 9 is a cross-sectional view illustrating a modification of a base member in the embodiment of the invention.

### MODE(S) FOR CARRYING OUT THE INVENTION

Hereinafter, an embodiment of the invention will be described with reference to the drawings.

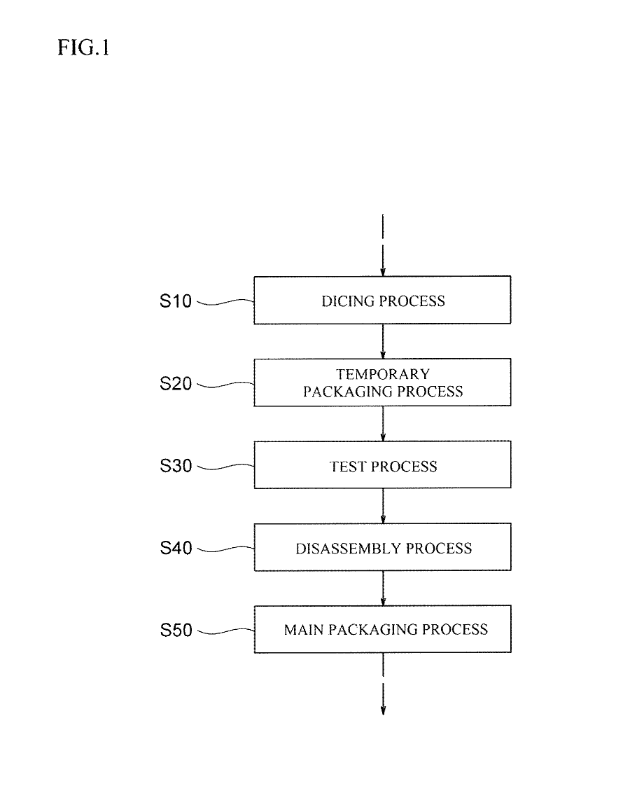

FIG. 1 is a flowchart illustrating a portion of a device manufacturing process in the present embodiment.

In the present embodiment, an electronic circuit which is incorporated into a die 90 is tested after a semiconductor wafer is diced (after Step S10 in FIG. 1) and before final packaging is performed (before Step S50) (Steps S20 to S40).

In the present embodiment, first, the die 90 is temporarily mounted on a test carrier 10 by a carrier assembly apparatus (not illustrated) (Step S20). Then, the die 90 is electrically connected to a testing apparatus (not illustrated) via the test carrier 10, and an electronic circuit formed in the die 90 is tested (Step S30). After the test ends, the die 90 is taken out of the test carrier 10 (Step S40) and main packaging is performed on the die 90. In this way, a device is completed as a final product.

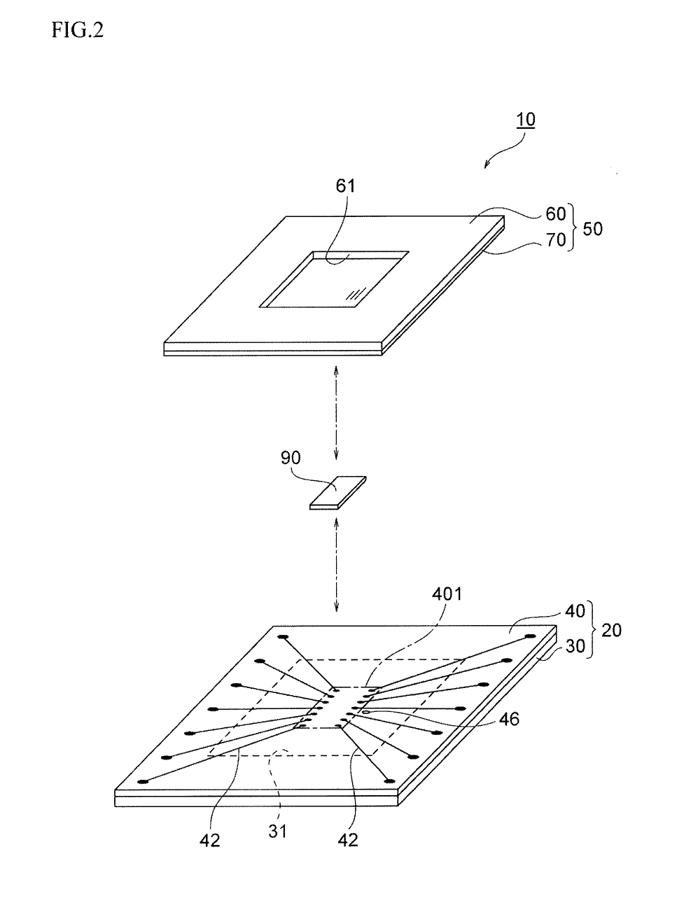

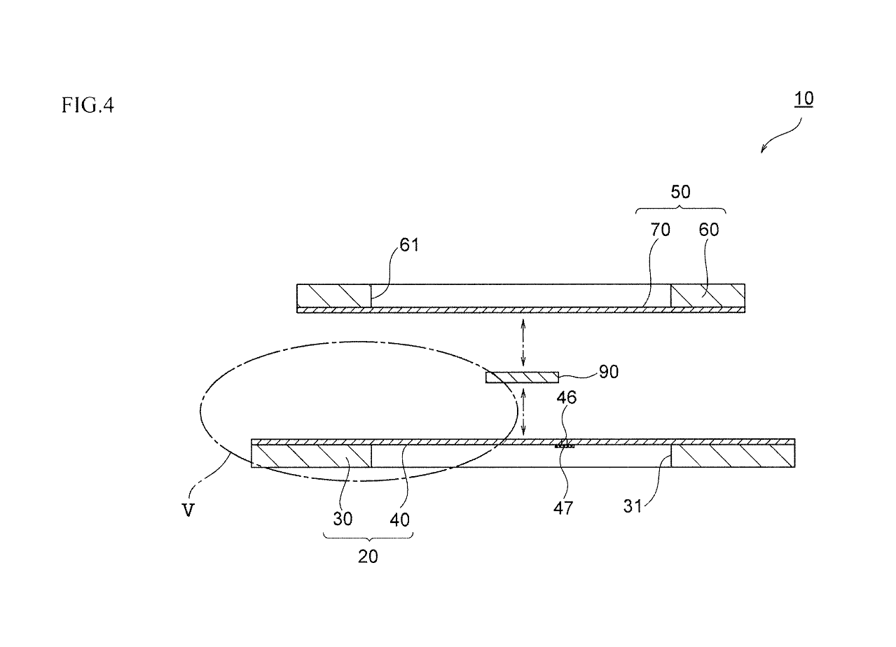

Next, the structure of the test carrier 10 on which the die 90 is temporarily mounted (temporarily packaged) in the present embodiment will be described with reference to FIGS. 2 to 9.

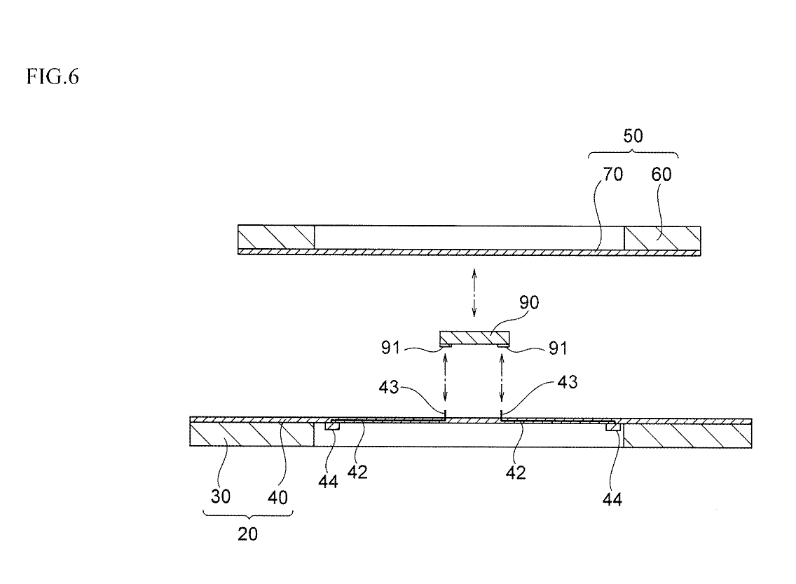

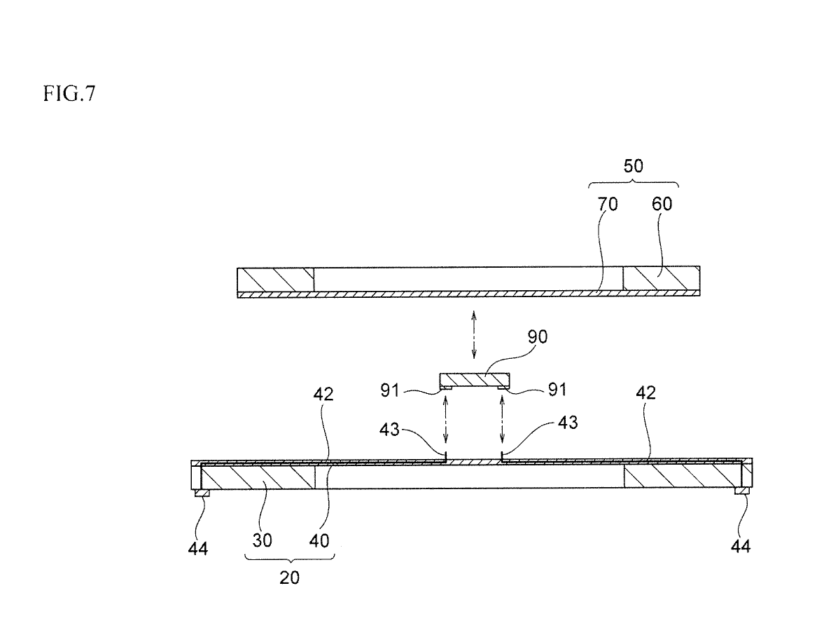

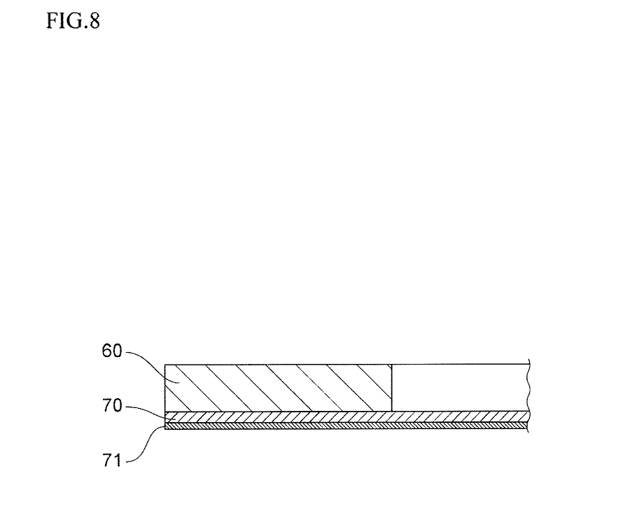

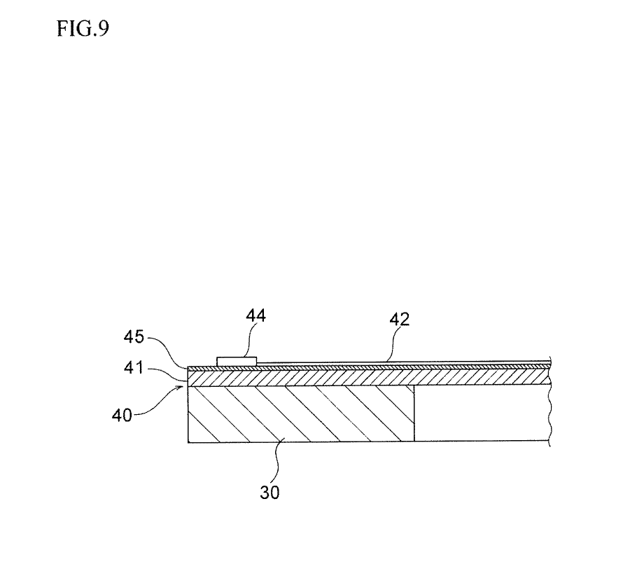

FIGS. 2 to 5 are diagrams illustrating the test carrier in the present embodiment. FIGS. 6 and 7 are diagrams illustrating modifications of the test carrier in the present embodiment. FIG. 8 is a diagram illustrating a modification of a cover member in the present embodiment. FIG. 9 is a diagram illustrating a modification of a base member in the present embodiment.

As illustrated in FIGS. 2 to 4, the test carrier 10 in the present embodiment includes: a base member 20 on which the die 90 is placed; and a cover member 50 which overlaps the base member 20 so as to cover the die 90. The die 90 is interposed between the base member 20 and the cover member 50 so that the test carrier 10 holds the die 90. The die 90 in the present embodiment corresponds to an example of an electronic device to be tested in the invention.

The base member 20 includes a base frame 30 and a base film 40. The base film 40 in the present embodiment corresponds to an example of a first member in the invention.

The base frame 30 is a rigid board that has high rigidity (higher rigidity than at least the base film 40) and has an opening 31 formed at the center thereof. As the material forming the base frame 30, a polyimide resin, a polyamide-imide resin, a glass epoxy resin, ceramics, or glass is exemplified.

Meanwhile, the base film 40 is a flexible film and is stuck to the entire surface of the base frame 30 including the central opening 31 by an adhesive (not illustrated). In the present embodiment, since the base film 40 with flexibility is stuck to the base frame 30 with high rigidity, the handling ability of the base member 20 is improved.

The base frame 30 may be omitted and the base member may include only the base film 40. Alternatively, the base film 40 may be omitted and a rigid printed wiring board in which a wiring pattern is formed on a base frame without the opening 31 may be used as the base member.

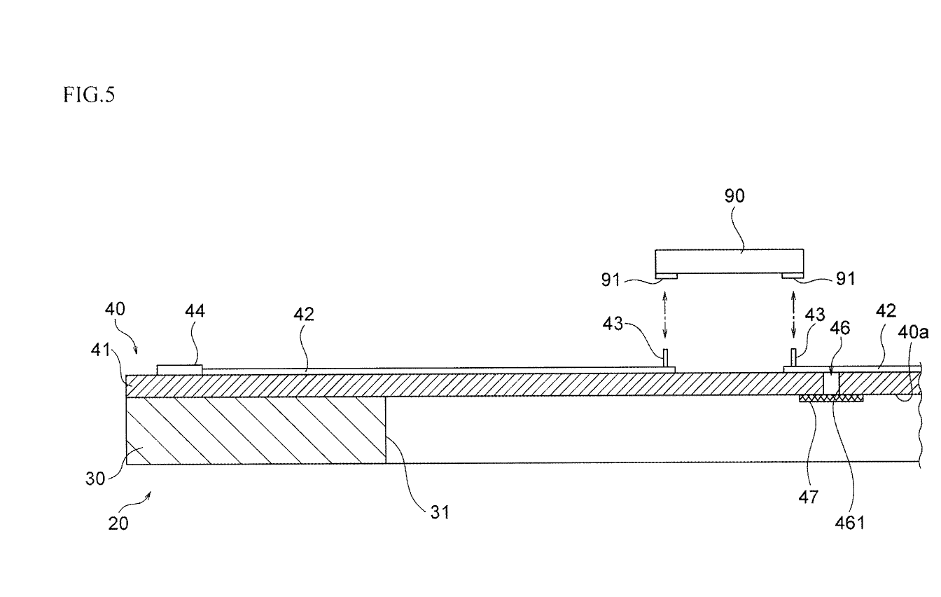

As illustrated in FIG. 5, the base film 40 includes a film body 41 and a wiring pattern 42 which is formed on the surface of the film body 41. The film body 41 is, for example, a polyimide film. The wiring pattern 42 is formed by, for example, etching a copper film laminated on the film body 41. In addition, a cover layer, which is constituted by, for example, a polyimide film, may be laminated on the film body 41 to protect the wiring pattern 42 or a so-called multi-layer flexible printed wiring board may be used as the base film.

As illustrated in FIG. 5, a bump 43 is provided at one end of the wiring pattern 42 in a standing manner so as to electrically contact an electrode pad 91 of the die 90. The bump 43 is made of, for example, copper (Cu) or nickel (Ni) and is formed on the end of the wiring pattern 42 by, for example, a semi-additive method.

Meanwhile, an external terminal 44 is formed at the other end of the wiring pattern 42. When the electronic circuit formed on the die 90 is tested, a contactor (not illustrated) of the testing apparatus electrically contacts the external terminal 44, and the die 90 is electrically connected to the testing apparatus through the test carrier 10.

Note that, the wiring pattern 42 is not limited to the above-mentioned structure. Although not particularly illustrated in the drawings, for example, a portion of the wiring pattern 42 may be formed in real time on the surface of the base film 40 by an ink-jet printing method. Alternatively, the entire wiring pattern 42 may be formed by the ink-jet printing method.

In FIG. 5, only two electrode pads 91 are illustrated. However, in practice, a large number of electrode pads 91 are formed on the die 90 and a large number of bumps 43 are formed on the base film 40 so as to correspond to the electrode pads 91.

The position of the external terminal 44 is not limited to the above-mentioned position. For example, as illustrated in FIG. 6, the external terminal 44 may be formed on the lower surface of the base film 40. Alternatively, as illustrated in FIG. 7, the external terminal 44 may be formed on the lower surface of the base frame 30. In the example illustrated in FIG. 7, a through hole or a wiring pattern is formed in or on the base frame 30, in addition to the base film 40, so as to electrically connect the bump 43 and the external terminal 44.

Although not particularly illustrated in the drawings, the wiring pattern or the external terminal may be formed on a cover film 70, in addition to the base film 40, or the external terminal may be formed on a cover frame 60.

In the present embodiment, as illustrated in FIGS. 2 to 5, a through hole 46 is formed in the base film 40. The through hole 46 has an inside diameter of, for example, about a few hundreds of micrometers and is arranged in the vicinity of a region 401 (see FIG. 2) of the upper surface of the base film 40 which comes into contact with the die 90. The through hole 46 in the present embodiment corresponds to an example of a connection means in the invention.

As described later, when the die 90 is interposed between the base member 20 and the cover member 50, an accommodation space 11 is formed between the base film 20 and the cover member 50. The accommodation space 11 communicates with the outside through the through hole 46 formed in the base film 20. Therefore, air which remains in the accommodation space 11 can be discharged to the outside through the through hole 46.

Note that, in the example illustrated in FIGS. 2 to 5, only one through hole 46 is formed in the base film 20. However, a plurality of through holes 46 may be formed in the vicinity of a contact region 201 of the base film 20. In addition, the through hole may be formed in the cover film 70, instead of the base film 40, or the through hole may be formed in both the base film 20 and the cover film 70.

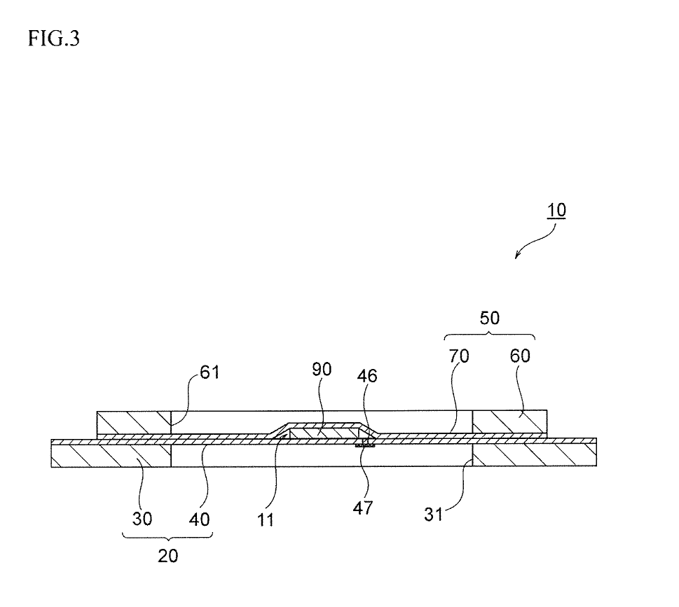

In the present embodiment, as illustrated in FIGS. 3 to 5, a filter 47 is stuck to an outer surface 40a of the base film 40 through an adhesive. The filter 47 has a mesh having an opening with a size of, for example, about 0.2 μm and covers an outer opening 461 of the through hole 46.

The filter 47 allows air to flow from the accommodation space 11 to the outside through the through hole 46 and prevents an object, such as dust, from entering the accommodation space 11 from the outside through the through hole 46. The filter 47 in the present embodiment corresponds to an example of a prohibition means in the invention.

Although not particularly illustrated in the drawings, a valve may be provided in the opening 461 of the through hole 46, instead of the filter 47. The valve is, for example, a one-way valve that allows air to flow from the accommodation space 11 to the outside through the through hole 46 and prevents air from flowing from the outside into the accommodation space 11 through the through hole 46. The valve prohibits dust from entering the accommodation space 11.

As illustrated in FIGS. 2 to 4, the cover member 50 includes the cover frame 60 and the cover film 70. The cover film 70 in the present embodiment is an example of a second member in the invention.

The cover frame 60 is a rigid plate that has high rigidity (higher rigidity than at least the base film 40) and has an opening 61 formed at the center thereof. The cover frame 60 is made of, for example, glass, a polyimide resin, a polyamide-imide resin, a glass epoxy resin, or ceramics.

The cover film 70 in the present embodiment is a film made of an elastic material that has a lower Young's modulus (lower hardness) than the base film 40 and has a self-adhesive property (stickiness) so as to be more flexible than the base film 40. As an example of the material forming the cover film 70, silicon rubber or polyurethane is exemplified. The term “self-adhesive property” means a property that can adhere to an object without using an adhesive or bond. In the present embodiment, the base member 20 and the cover member 50 are integrated by the self-adhesive property of the cover film 70, instead of the reduced pressure method according to the related art.

As illustrated in FIG. 8, the cover film 70 may be made of a material having a lower Young's modulus than the base film 40 and, for example, silicon rubber may be coated on the surface of the film 70 so as to form a self-adhesive layer 71, thereby giving the self-adhesive property to the cover film 70.

Alternatively, the cover film 70 may be made of a material having a lower Young's modulus than the base film 40 and, for example, silicon rubber may be coated on the upper surface of the base film 40 so as to form a self-adhesive layer 45, thereby giving the self-adhesive property to the base film 40, as illustrated in FIG. 9.

Both the cover film 70 and the base film 40 may have the self-adhesive property.

Returning to FIGS. 2 to 4, the cover film 70 is stuck to the entire surface of the cover frame 60 including the central opening 61 by an adhesive (not illustrated). In the present embodiment, since the flexible cover film 70 is stuck to the cover frame 60 with high rigidity, the handling ability of the cover member 50 is improved. The cover member 50 may include only the cover film 70.

The test carrier 10 that is explained above is assembled as follows.

That is, first, the cover member 50 is reversed, and the die 90 is placed on the cover film 70 in a status that the electrode pads 91 are upward. As illustrated in FIG. 9, when the base film 40 has the self-adhesive property, the die 90 is placed on the base film 40.

At that time, in the present embodiment, as described above, since the cover film 70 has the self-adhesive property, it is possible to temporarily fix the die 90 to the cover film 70 only by placing the die 90 on the cover film 70.

Then, the base member 20 overlaps the cover member 50 such that the die 90 is accommodated in the accommodation space 11 formed between the base film 40 and the cover film 70. Thereby, the die 90 is interposed between the base film 40 and the cover film 70.

At that time, in the present embodiment, since the cover film 70 has the self-adhesive property, the base film 40 and the cover film 70 are stuck to each other only by close contact therebetween, and the base member 20 and the cover member 50 are integrated with each other.

In the present embodiment, the cover film 70 is more flexible than the base film 40, and the tension of the cover film 70 is increased by a value corresponding to the thickness of the die 90. The die 90 is pressed against the base film 40 by the tension of the cover film 40. Therefore, it is possible to prevent the positional deviation of the die 90.

A resin layer, such as a resist layer, may be formed on a portion of the base film 40 on which the wiring pattern 42 is formed. In this case, since the unevenness due to the wiring pattern 42 is reduced, the bonding between the base film 40 and the cover film 70 is strengthened.

The test carrier 10 thus assembled is carried to the testing apparatus which is not particularly illustrated. The contactor of the testing apparatus electrically contacts the external terminal 44 of the test carrier 10, and the electronic circuit of the die 90 is electrically connected to the testing apparatus through the test carrier 10. The electronic circuit of the die 90 is tested.

When a heating test is performed on the die, the accommodation space of the test carrier is heated together with the die. If the through hole 46 is not formed in the test carrier, air which remains in the accommodation space expands and the positional deviation of the die occurs. As a result, the electrode pad of the die deviates from the bump on the base film and a poor contact occurs, which makes it difficult to perform the test in some cases. In contrast, in the present embodiment, even when air remains in the accommodation space 11 of the test carrier 10, it is possible to stably perform the heating test because the air is discharged to the outside through the through hole 46.

Note that, the embodiments explained above are described for facilitating understanding of the present invention and are not described for limiting the present invention. Therefore, the elements disclosed in the above embodiment include all design modifications and equivalents falling under the technical scope of the present invention.

### EXPLANATIONS OF LETTERS OR NUMERALS

10 TEST CARRIER
11 ACCOMMODATION SPACE
20 BASE MEMBER
30 BASE FRAME
40 BASE FILM
40a OUTER SURFACE
401 CONTACT REGION
41 FILM BODY
42 WIRING PATTERN
43 BUMP
44 EXTERNAL TERMINAL
46 THROUGH HOLE
461 OPENING
47 FILTER
50 COVER MEMBER
60 COVER FRAME
70 COVER FILM
90 DIE
91 ELECTRODE PAD

1. A test carrier configured to accommodate an electronic device to be tested, comprising:
a connector configured to connect an internal space to an outside,
wherein the internal space accommodates the electronic device to be tested.

2. The test carrier according to claim 1, further comprising:
a prohibition device configured to allow a flow of gas from the internal space to the outside through the connector and configured to prohibit an object from entering the internal space from the outside through the connector.

3. A test carrier comprising:
a first member that holds an electronic device to be tested; and
a second member that has a film shape and overlaps the first member so as to cover the electronic device to be tested,
wherein at least one of the second member and the first member has a self-adhesive property,
the second member is more flexible than the first member,
at least one of the first member and the second member has a through hole, and
the through hole is formed in the vicinity of a region of at least one of the first member and the second member which contacts the electronic device to be tested.

4. The test carrier according to claim 3, further comprising:
a filter that is stuck to at least one of the first member and the second member so as to cover an opening of the through hole.

5. The test carrier according to claim 3,
wherein the second member is made of a material with the self-adhesive property.

6. The test carrier according to claim 5,
wherein the second member is made of silicon rubber.

7. The test carrier according to claim 3,
wherein at least one of the second member and the first member has a surface on which a layer with the self-adhesive property is formed.
